(19) United States
(12) Patent Application Publication
(10) Pub. No.: US 2008/0099824 A1
(43) Pub. Date: May 1, 2008

(54) Flash memory device and method of fabricating the same

(75) Inventor: Hyun-Sil Oh, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/892,739

(22) Filed: Aug. 27, 2007

(30) Foreign Application Priority Data
Oct. 31, 2006 (KR) 10-2006-0106534

(51) Int. Cl. H01L 29/788; H01L 21/336

(52) U.S. Cl. 257/316; 438/266; 257/E29.3; 257/E21.422

(57) ABSTRACT

A flash memory device and a method of fabricating the same are provided. The flash memory device may include an isolation layer provided in a semiconductor substrate to define an active region. A floating gate may be provided on the active region. The floating gate may be spaced a first distance apart from the active region. A control gate may be provided, which covers a top surface of the floating gate and one of both sidewalls of the floating gate adjacent to the active region. The portion of the control gate covering one sidewall of the floating gate may be spaced a second distance, which may be greater than the first distance, apart from the active region.

### PRIORITY STATEMENT

This application claims priority under 35 USC § 119 to Korean Patent Application No. 10-2006-0106534, filed on Oct. 31, 2006, in the Korean Intellectual Property Office (KIPO), the entire contents of which are incorporated herein by reference.

### BACKGROUND

1. Field

Example embodiments relate to a semiconductor device and a method of fabricating the same. Other example embodiments relate to a flash memory device and a method of fabricating the same.

2. Description of the Related Art

Flash memory devices may be classified into NOR type flash memory devices capable of high speed random access, and NAND type flash memory devices having improved program and erase speeds and capable of high-integration according to the structure of a cell array. Program and erase operations of the flash memory devices may be in direct relation to a coupling ratio of a unit cell. The program operation of the flash memory devices may be performed by Flowler-Nordheim (FN) tunneling and/or hot electron injection. The erase operation of the flash memory devices may also be performed by FN tunneling.

The FN tunneling may occur when a relatively strong electrical field is applied to a tunnel oxide layer interposed between a floating gate and a substrate. The electrical field between the floating gate and the substrate may be substantially induced by applying a relatively high voltage of about 15V to about 20V to a control gate disposed over the floating gate. To reduce the program or erase voltage, increasing the coupling ratio of the unit cell of the flash memory device may be necessary.

FIG. 1 is a cross-sectional view of a conventional flash memory device.

Referring to FIG. 1, first and second control gates 9a and 9b, crossing over an active region of a semiconductor substrate 1, may be provided. The first and second control gates 9a and 9b may serve as a word line. A first floating gate 5a may be interposed between the first control gate 9a and the active region of the semiconductor substrate 1, and a second floating gate 5b may be interposed between the second control gate 9b and the active region of the semiconductor substrate 1. For example, the first and second floating gates 5a and 5b may be provided on one active region.

Inter-gate dielectric layers 7 may be interposed between the first and second floating gates 5a and 5b, and the first and second control gates 9a and 9b. In addition, the first and second floating gates 5a and 5b may be insulated from the active region of the semiconductor substrate 1 by a tunnel oxide layer 3. A plurality of source and drain regions 11 may be provided in the active region of the semiconductor substrate 1. The source and drain regions 11 may be disposed on both sides of channel regions under the first and second floating gates 5a and 5b.

A plurality of flash memory cells may be provided on the semiconductor substrate 1. For example, a first flash memory cell CL1 may be provided on an intersection of the first control gate 9a and the active region of the semiconductor substrate 1, and a second flash memory cell CL2 may be provided on an intersection of the second control gate 9b and the active region of the semiconductor substrate 1.

A parasitic coupling capacitor C may be provided between the first and second floating gates 5a and 5b. A capacitance of the coupling capacitor C may increase as the distance between the first and second floating gates 5a and 5b decreases. In other words, as integration of the flash memory device increases, an inter-floating gate coupling capacitance may also increase. When the first flash memory cell CL1 is selectively programmed, electrons may be injected into the first floating gate 5a, thereby changing an electrical potential thereof, and an electrical potential of the second floating gate 5b adjacent to the first floating gate 5a may also be changed due to the coupling capacitor C. A threshold voltage of the second flash memory cell CL2 may be changed. A read error may occur in an operation mode for selectively reading data stored in one cell in strings of the NAND type flash memory device including the second flash memory cell CL2.

A NAND type flash memory device in relation to the inter-floating gate coupling capacitance, and a method of fabricating the same are disclosed in the related art. According to the related art, the inter-floating gate coupling capacitance between floating gates respectively formed on different active regions with an isolation layer interposed therebetween may be reduced. However, in the structure of the flash memory device disclosed by the related art, there may be a limit in reducing the inter-floating gate coupling capacitance between the floating gates formed on one active region.

To increase a cell coupling ratio directly affecting program efficiency and erasure efficiency of flash memory cells, the capacitance of the inter-gate dielectric layer 7 may be increased. Generally, an oxide/nitride/oxide (ONO) layer may be used as the inter-gate dielectric layer 7. Recently, research for utilizing a high-k dielectric layer, which has a higher dielectric constant than the ONO layer, as the inter-gate dielectric layer 7 instead of the ONO layer, is progressing. However, as is generally known, the high-k dielectric layer may have increased etch resistance. Such difficulty of a dry etching process due to the etch resistance of the high-k dielectric layer is disclosed in the related art. As such, there may be difficulty in dry-etching the high-k dielectric layer, and thus it may be very difficult to mass produce flash memory devices using the high-k dielectric layer, which has higher etch resistance and a dielectric constant than the ONO layer, as an inter-gate dielectric layer.

### SUMMARY

Example embodiments provide a flash memory device which may suppress an inter-floating gate capacitance and improve a coupling ratio. Other example embodiments provide a method of fabricating a flash memory device which may suppress an inter-floating gate capacitance and improve a coupling ratio.

In example embodiments, a flash memory device which may suppress an inter-floating gate capacitance and improve a coupling ratio, is provided. The flash memory device may include an isolation layer provided in a semiconductor substrate to define an active region. A floating gate may be provided on the active region. The floating gate may be spaced a first distance apart from the active region. A control gate may be provided, which covers a top surface of the floating gate and one of both sidewalls of the floating gate adjacent to the active region. The portion of the control gate covering one sidewall of the floating gate may be spaced a second distance, which may be greater than the first distance, apart from the active region.

In example embodiments, both edges of an upper region of the floating gate may overlap the isolation layer. A lower region of the floating gate may be self-aligned with the active region. In other example embodiments, the control gate may extend to the isolation layer, and cover sidewalls of the floating gate adjacent to the isolation layer. The isolation layer may have a projecting portion on a higher level than the active region. The control gate may have an extension extending into the projecting portion of the isolation layer.

In still other example embodiments, the flash memory device may further include a tunnel oxide layer between the floating gate and the active region, and an inter-gate dielectric layer between the floating gate and the control gate. The inter-gate dielectric layer may include at least one of an oxide/nitride/oxide layer, an aluminum oxide layer, a hafnium oxide layer, a hafnium silicon oxide layer, a hafnium aluminum oxide layer, a tantalum oxide layer, a zirconium oxide layer, a lanthanum oxide layer, and a titanium oxide layer.

The flash memory device may further include lower and upper blocking insulating layers which may be sequentially stacked on the active region adjacent to both sidewalls of the floating gate. The upper blocking insulating layer may be disposed on a lower level than the control gate.

The lower blocking insulating layer may be connected to the tunnel oxide layer, and formed of the same material as the tunnel oxide layer. The upper blocking insulating layer may be connected to the inter-gate dielectric layer, and formed of the same material as the inter-gate dielectric layer. The flash memory device may further include an intermediate blocking insulating layer between the lower blocking insulating layer and the upper blocking insulating layer. In yet other example embodiments, the flash memory device may further include source and drain regions provided in the active region adjacent to both sidewalls of the floating gate.

A method of fabricating a flash memory device, which may suppress an inter-floating gate capacitance and increase a coupling ratio, is provided. The method may include forming an isolation layer defining an active region in a semiconductor substrate. A first dielectric layer may be formed on the substrate having the isolation layer. A floating gate partially covering the active region may be formed on the substrate having the first dielectric layer. A second dielectric layer may be formed on the entire surface of the substrate having the floating gate. The first and second dielectric layers may be sequentially stacked on the active region adjacent to both sidewalls of the floating gate. A control gate covering a top surface of the floating gate and one of both sidewalls of the floating gate adjacent to the active region may be formed on the substrate having the second dielectric layer.

In example embodiments, both edges of an upper region of the floating gate may be formed to overlap the isolation layer. A lower region of the floating gate may be formed to be self-aligned with the active region. In other example embodiments, after forming the floating gate, source and drain regions may be further formed in the active region adjacent to both sidewalls of the floating gate. In still other example embodiments, after forming the floating gate, a gate re-oxidation process for curing the first dielectric layer adjacent to both sidewalls of the floating gate and rounding a lower corner of the floating gate may be further performed.

In example embodiments, after forming the floating gate, an intermediate blocking insulating layer covering an upper portion of the active region adjacent to both sidewalls of the floating gate may be further formed. Forming the intermediate blocking insulating layer may include forming an insulating layer on the substrate having the floating gate, and etching-back the insulating layer. The isolation layer may be formed to have a projecting portion on a higher level than the active region. While etching-back the insulating layer, the projecting portion of the isolation layer may be partially etched to form a recessed region.

The control gate may be formed to have an extension covering sidewalls of the upper region of the floating gate adjacent to the isolation layer and filling the recessed region. In yet other example embodiments, the control gate may be formed to cover sidewalls of the floating gate adjacent to the isolation layer.

### BRIEF DESCRIPTION OF THE DRAWINGS

Example embodiments will be more clearly understood from the following detailed description taken in conjunction with the accompanying drawings. FIGS. 1-3F represent non-limiting, example embodiments as described herein.

FIG. 1 is a cross-sectional view of a conventional flash memory device.

FIG. 2 is a plan view of a flash memory device according to example embodiments.

FIGS. 3A to 3F are cross-sectional views illustrating a method of fabricating a flash memory device according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully hereinafter with reference to the accompanying drawings, in which example embodiments are shown. Example embodiments may, however, be embodied in different forms and should not be construed as limited to the embodiments set forth herein. Rather, these embodiments are provided so that this disclosure is thorough and complete and fully conveys the scope of example embodiments to those skilled in the art. In the drawings, the thicknesses of layers and regions are exaggerated for clarity. The same reference numerals are used to denote the same elements throughout the specification.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

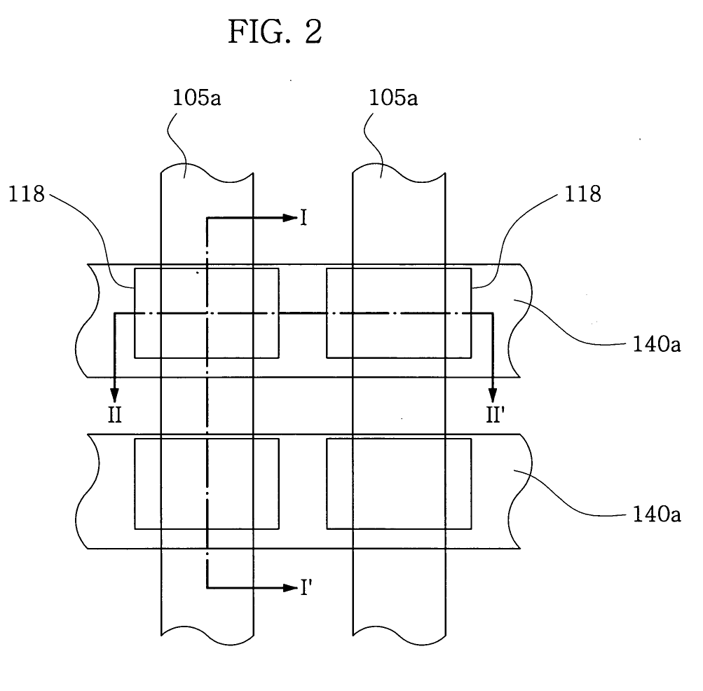

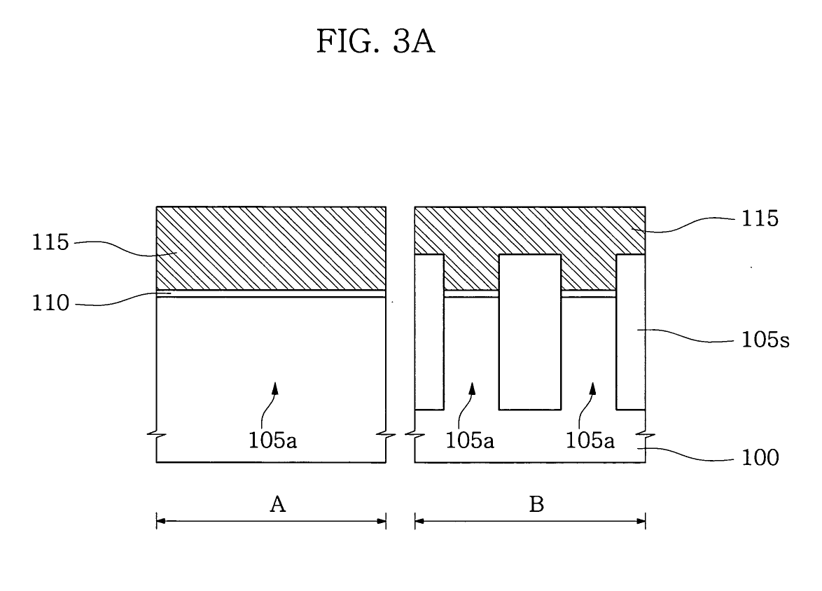

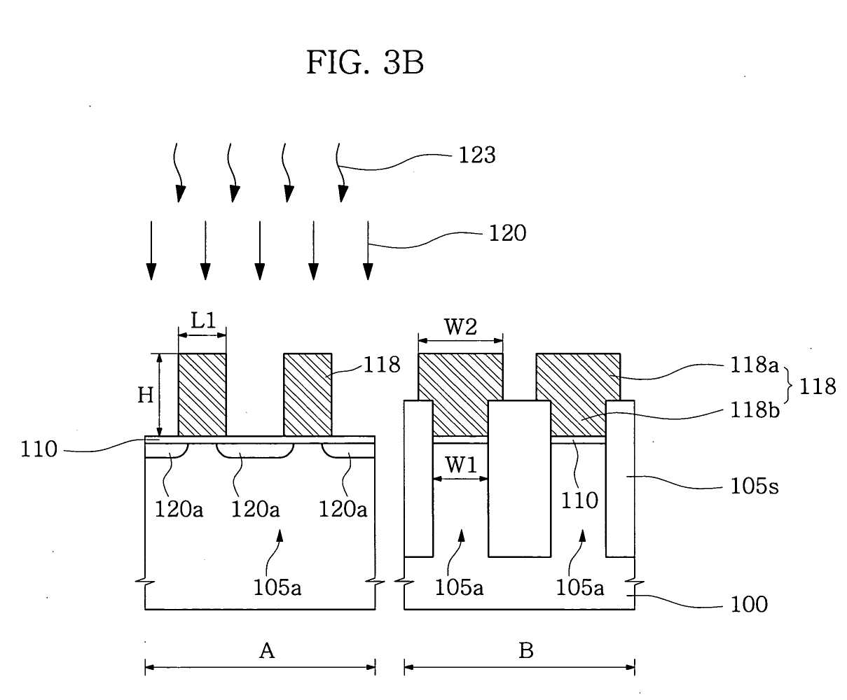

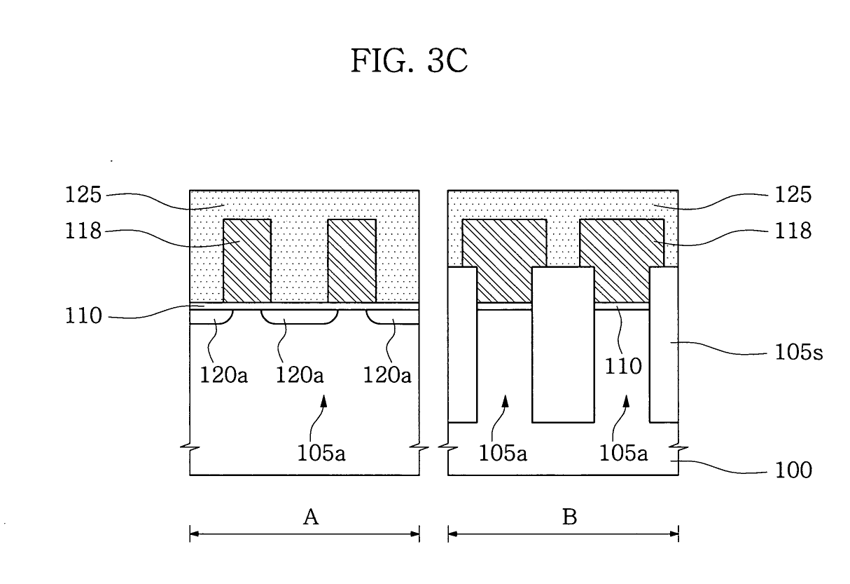

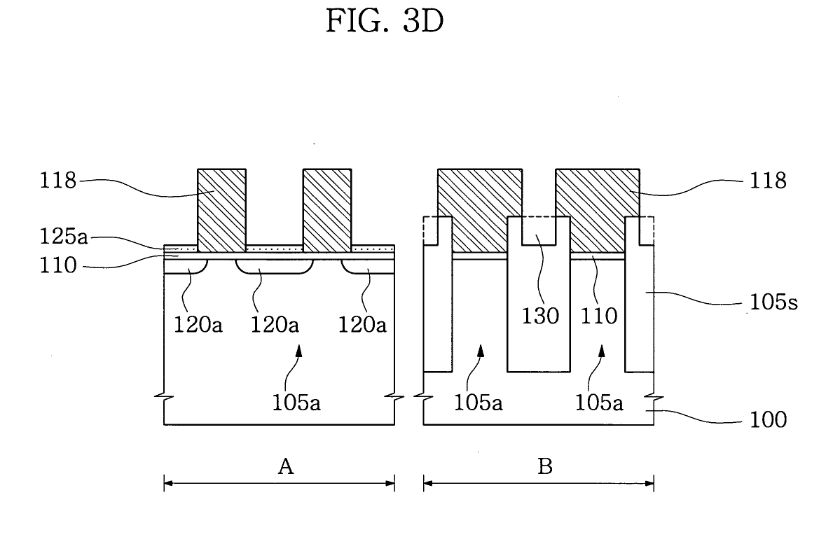

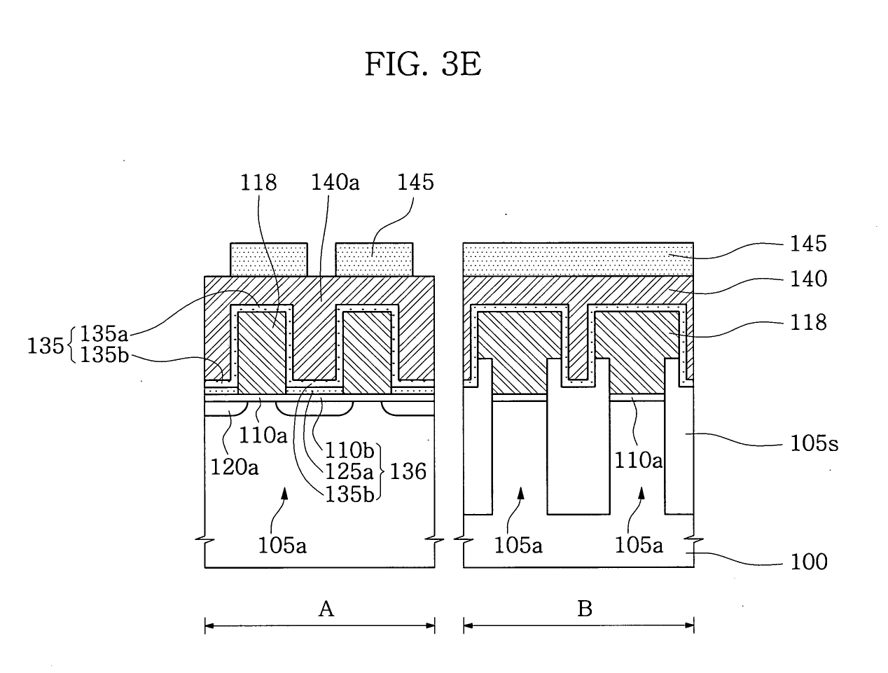

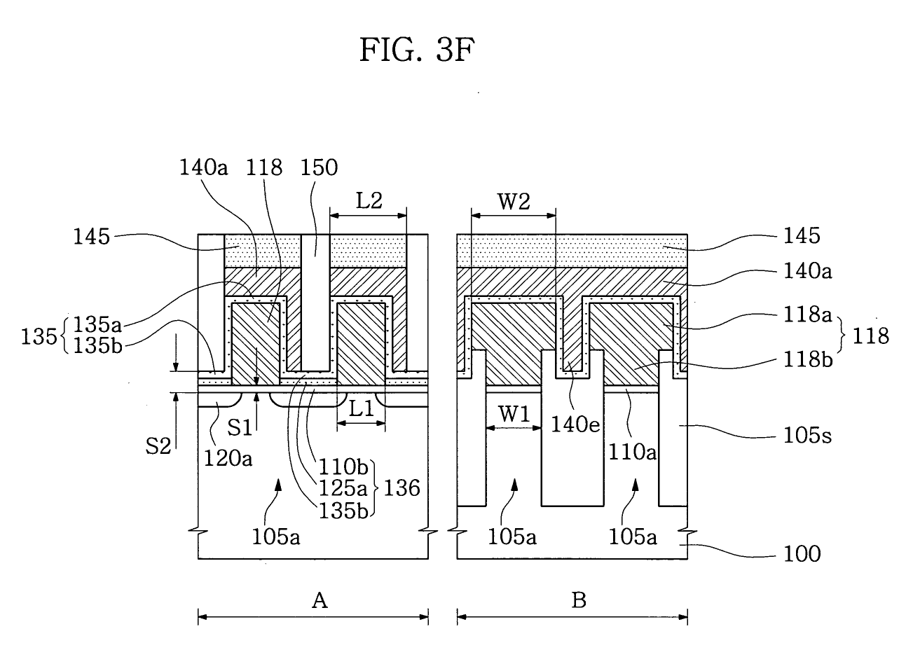

FIG. 2 is a plan view of a flash memory device according to example embodiments, and FIGS. 3A to 3F are cross-sectional views illustrating a method of fabricating a flash memory device according to example embodiments. Throughout FIGS. 3A to 3F, reference symbol “A” denotes a region taken along line I-I′ of FIG. 2, and reference symbol “B” denotes a region taken along line II-II′ of FIG. 2. The structure of a flash memory device according to example embodiments will be described with reference to FIGS. 2 and 3F.

Referring to FIGS. 2 and 3F, an isolation layer 105s defining at least one active region 105a may be provided in a semiconductor substrate 100. The isolation layer 105s may be formed by a trench isolation technique. A plurality of active regions 105a may be provided. For example, the active regions 105a may be disposed parallel to one another. The isolation layer 105s may have a projecting portion disposed on a higher level than the surface of the active region 105a.

At least one floating gate 118 may be provided on the active region 105a. The floating gate 118 may be spaced a first distance S1 apart from the active region 105a. A plurality of floating gates 118 may be provided. The floating gates 118 may be arranged in two dimensions on the active region 105a. The floating gate 118 may be formed of a conductive layer, e.g., a polysilicon layer. In terms of increased integration, a height H of the floating gate 118 may be greater than a width L1 of the floating gate 118 in a longitudinal direction of the active region 105a. Also, the greater the height H of the floating gate 118 is desirable in terms of coupling ratio.

Both edges of the floating gate 118 may overlap the isolation layer 105s. For example, both edges of an upper region 118a of the floating gate 118 may overlap the isolation layer 105s. Also, a lower region 118b of the floating gate 118 may be self-aligned with the active region 105a. In other words, the lower region 118b of the floating gate 118 may be self-aligned with the active region 105a by being interposed between the projecting portions of the isolation layer 105s. A tunnel oxide layer 110a may be interposed between the floating gate 118 and the active region 105a. The tunnel oxide layer 110a may be a thermal oxide layer and/or a high-k dielectric layer.

A control gate 140a covering the floating gate 118 and an upper portion of the active region 105a, which may be adjacent to one of both sidewalls of the floating gate 118, is provided. For example, the control gate 140a may cover a top surface of the floating gate 118 and one of both sidewalls of the floating gate 118 adjacent to the active region 105a as well as the upper portion of the active region 105a adjacent to one of both sidewalls of the floating gate 118. The portion of the control gate 140a covering one sidewall of the floating gate 118 may be spaced apart a second distance S2 greater than the first distance S1 from the active region 105a. In addition, in a longitudinal direction of the active region 105a, a width L2 of the control gate 140a may be greater than the width L1 of the floating gate 118. The control gate 140a may extend to the isolation layer 105s, thereby covering the sidewalls of the floating gate 118 adjacent to the isolation layer 105s.

When the isolation layer 105s has the projecting portion, the control gate 140a may have an extension 140e extending into the projecting portion of the isolation layer 105s. Both sidewalls of the floating gate 118 adjacent to the isolation layer 105s may be covered by the extension 140e of the control gate 140a. A mask pattern 145 exposing a predetermined or given region of the control gate may be formed on the control gate 140a.

As illustrated in region “B” of FIG. 3F, when the upper region 118a of the floating gate 118 has a greater width than the lower region 118b, the extension 140e of the control gate 140a may cover sidewalls of the upper region 118a of the floating gate 118, which may be adjacent to the isolation layer 105s, and have a bottom surface disposed on a lower level than the upper region 118a of the floating gate 118.

An inter-gate dielectric layer 135a may be interposed between the floating gate 118 and the control gate 140a. The inter-gate dielectric layer 135a may include an oxide/nitride/oxide (ONO) layer and/or a high-k dielectric layer having a higher etch resistance than the ONO layer. For example, the inter-gate dielectric layer 135a may include at least one of an ONO layer, an aluminum oxide (AlO) layer, a hafnium oxide (HfO) layer, a hafnium silicon oxide (HfSiO) layer, a hafnium aluminum oxide (HfAlO) layer, a tantalum oxide (TaO) layer, a zirconium oxide (ZrO) layer, a lanthanum oxide (LaO) layer, and a titanium oxide (TiO) layer.

Lower and upper blocking insulating layers 110b and 135b may be provided, which may be sequentially stacked on the active region 105a adjacent to both sidewalls of the floating gate 118. The upper blocking insulating layer 135b may be disposed on a lower level than the control gate 140a. In other words, the lower and upper blocking insulating layers 110b and 135b may be interposed between a portion of the control gate 140a covering one sidewall of the floating gate 118, and the active region 105a. An intermediate blocking insulating layer 125a may be interposed between the lower blocking insulating layer 110b and the upper blocking insulating layer 135b. The intermediate blocking insulating layer 125a may include a silicon oxide layer.

The lower blocking insulating layer 110b and the tunnel oxide layer 110a may be connected to each other to form a first dielectric layer 110 (see FIG. 3D). For example, the lower blocking insulating 110b and the tunnel oxide layer 110a may be formed of the same material layer.

The upper blocking insulating layer 135b and the inter-gate dielectric layer 135a may be connected to each other to form a second dielectric layer 135. Because the upper blocking insulating layer 135b and the inter-gate dielectric layer 135a may be connected to each other, one sidewall of the floating gate 118, which may be adjacent to the active region 105a and covered by the control gate 140a, and the other sidewall of the floating gate 118 facing the same may be covered by the second dielectric layer 135. The upper blocking insulating layer 135b and the inter-gate dielectric layer 135a may be formed of the same material layer.

A spacer insulating layer 150 may be provided, which covers the sidewalls of the control gate 140a, and the sidewall of the floating layer 118 that is not covered by the control gate 140a. The spacer insulating layer 150 may include a silicon oxide layer and/or a silicon nitride layer.

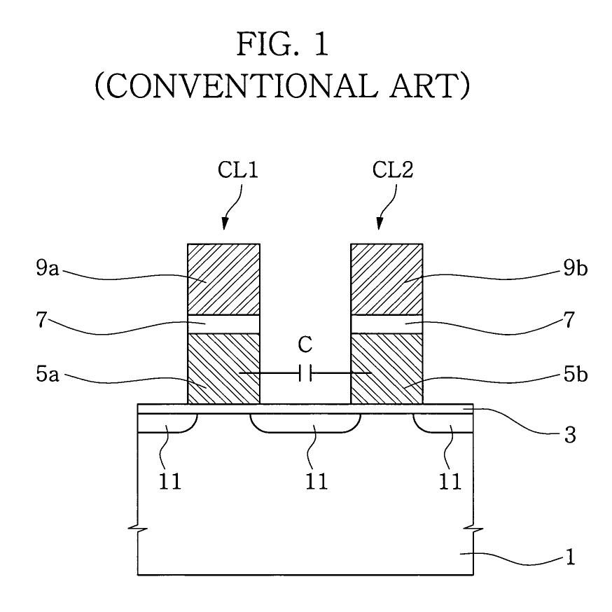

As described above, the control gate 140a may cover a top surface of the floating gate 118, one sidewall of the floating gate 118 that may be adjacent to the active region 105a, and both sidewalls of the floating gate 118 that may be adjacent to the isolation layer 105s. Because the area in which the control gate 140a and the floating gate 118 face each other is larger than that of the conventional flash memory device illustrated in FIG. 1, the coupling ratio may increase compared to the conventional art. The inter-gate dielectric layer 135a may be formed in the structure which is not etched, and thus a high-k dielectric layer having a higher etch resistance than an ONO layer, as well as the ONO layer, may be used as the inter-gate dielectric layer 135a.

When the plurality of floating gates 118 are provided on the active region 105a, an inter-floating gate coupling capacitance, which has been described with reference to FIG. 1, may be significantly reduced. When two floating gates 118 are provided in one active region 105a as illustrated in region “A” of FIG. 3F, the control gate 140a may exist between the adjacent floating gates 118. For example, because the control gate 140a, an electrical conductor, exists between the floating gates 118, the parasitic coupling capacitor as described in FIG. 1 may occur between the floating gates 118. When the plurality of active regions 105a are provided, a coupling capacitance between the floating gates 118 provided on the respective active regions 105a may be significantly reduced. The control gate 140a, an electrical conductor, may cover the sidewalls of the floating gates 118 adjacent to the isolation layer 105s.

While the floating gate 118 is spaced the first distance S1 apart from the active region 105a, the control gate 140a may be spaced a second distance S2 greater than the first distance S1 apart from the active region 105a in the portion covering one sidewall of the floating gate 118. Because the blocking insulating layer 136 is interposed between the control gate 140a whose portion covers one sidewall of the floating gate 118, and the active region 105a, a change in an electrical potential of the active region 105a, which is caused by an electrical field generated by the voltage applied to the control gate 140a, may be prevented or reduced. For example, the blocking insulating layer 136 may block the electrical field generated by the voltage applied to the control gate 140a, thereby preventing or retarding the change in the electrical potential of the source and drain regions 120a. A change in electrical characteristics of a transistor depending on the change in the potential of the source and drain regions 120a may be prevented or reduced. Consequently, the change in the potential of the active region 105a due to the electrical field generated by the voltage applied to the control gate 140a may be prevented or reduced, thereby preventing or reducing malfunction of the flash memory device.

For example, a Flowler-Nordheim (FN) tunneling mechanism may be used for a programming method of a cell in a NAND-type flash memory device. The FN tunneling may include applying an increased voltage to a control gate, setting substrate bias to about 0V, and injecting electrons in a channel region into a floating gate by floating source and drain regions. However, if an electrical potential of the floating source and drain regions is changed by a relatively strong electrical field caused by the increased voltage applied to the control gate, a program error of a cell may occur. Therefore, in example embodiments, the blocking insulating layer 136 may be interposed between the control gate 140a and the source and drain regions 120a, and thus the program error may be prevented or retarded from occurring in the flash memory device.

A method of fabricating a flash memory device according to example embodiments will now be described with reference to FIGS. 2, 3A to 3F. Referring to FIGS. 2 and 3A, a semiconductor substrate 100 may be prepared. For example, the semiconductor substrate 100 may be a single crystal silicon wafer. An isolation layer 105s defining at least one active region 105a may be formed in the semiconductor substrate 100. A plurality of active regions 105a may be provided. The active regions 105a may be disposed parallel to one another. Formation of the isolation layer 105s may include forming a trench region in a predetermined or given region of the semiconductor substrate 100, and forming an insulation layer filling the trench region. The isolation layer 105s may be formed to have a projecting portion projecting from a surface of the active region 105a by a predetermined or given height. A first dielectric layer 110 may be formed on the substrate having the isolation layer 105s. The first dielectric layer 110 may be a high-k dielectric layer and/or a thermal oxide layer. A floating gate conductive layer 115 may be formed on the substrate having the first dielectric layer 110. The floating gate conductive layer 115 may be a polysilicon layer.

Referring to FIGS. 2 and 3B, the floating gate conductive layer 115 (in FIG. 3A) may be patterned to form at least one floating gate 118 on the active region 105a. A plurality of floating gates 118 may be formed. The floating gates 118 may be two-dimensionally arranged on the active region 105a. The floating gate 118 may be formed to overlap the isolation layer 105s on both edges of an upper region 118a. A width W2 of the upper region 118a of the floating gate 118 in a width direction of the active region 105a may be formed greater than a width W1 of a lower region 118b thereof. The lower region 118b of the floating gate 118 may be formed to be self-aligned with the active region 105a. When the isolation layer 105s is formed to have a projecting portion, the upper region 118a of the floating gate 118 may be patterned and formed by photolithography and etching processes, and the lower region 118b of the floating gate 118 may be self-aligned with the active region 105a because it may be defined by the projecting portion. Both edges of the floating gate 118 may overlap the isolation layer 105s. Alternatively, the floating gate 118 in a width direction of the active region 105a may be formed to have the same width in both the upper region 118a and the lower region 118b.

In terms of increased integration, a height H of the floating gate 118 may be greater than a width L1 of the floating gate 118 in a longitudinal direction of the active region 105a. Additionally, the greater the height H of the floating gate 118 is desirable in terms of coupling ratio. An ion injection process may be performed on the substrate having the floating gate 118 to inject impurity ions 120 into the active region 105a adjacent to both sidewalls of the floating gate 118, and thus source and drain regions 120a may be formed.

While the floating gate conductive layer 115 (in FIG. 3A) is etched to form the floating gate 118, the first dielectric layer 110 adjacent to both sidewalls of the floating gate 118 may be thinner due to etching damage. A gate re-oxidation process 123 may be performed to round lower corners of the floating gate 118 as well as cure the first dielectric layer 110 adjacent to both sidewalls of the floating gate 118. The curing of the first dielectric layer 110 may include improving layer quality of the first dielectric layer 110 adjacent to both sidewalls of the floating gate 118, and curing the thickness of the first dielectric layer 110, which may be thinner due to etching damage, to the thickness of the first dielectric layer 110 under the floating gate 118. The gate re-oxidation process 123 may be for curing a dangling bond remaining on an interface of the first dielectric layer 110 under the floating gate 118. Also, because the lower corners of the floating gate 118 are rounded by the gate re-oxidation process 123, the electrical field may be concentrated on the lower corner of the floating gate 118. The gate re-oxidation process 123 may include at least one of a thermal oxidation process and a plasma oxidation process. The gate re-oxidation process, 123 may be performed in a gaseous atmosphere including oxygen. As illustrated in FIG. 3C, a buffer insulating layer 125 may be formed on the substrate on which the gate re-oxidation process 123 is performed. The buffer insulating layer 125 may include a silicon oxide layer.

Referring to FIGS. 2 and 3D, the buffer insulating layer 125 (in FIG. 3C) may be etched-back, thereby forming an intermediate blocking insulating layer 125a, which remains around the floating gate 118. The intermediate blocking insulating layer 125a may be disposed on a lower level than a top surface of the floating gate 118. When a plurality of floating gates 118 are provided, the intermediate blocking insulating layer 125a may be formed to partially fill a space between the floating gates 118.

During the formation of the intermediate blocking insulating layer 125a, the projecting portion of the isolation layer 105s projecting from the surface of the active region 105a by a predetermined or given height may be etched, and thus a recessed region 130 may be formed. While etching-back the buffer insulating layer 125, the buffer insulating layer 125 (in FIG. 3C) over the active region 105a may be etched, and the buffer insulating layer 125 (in FIG. 3C) over the isolation layer 105s may also be etched.

When the isolation layer 105s is exposed by etching the buffer insulating layer 125 (in FIG. 3C) over the isolation layer 105s, the buffer insulating layer 125 (in FIG. 3C) over the active region 105a may be etched to have a top surface disposed on substantially the same level as the top surface of the isolation layer 105s. Then, as the buffer insulating layer 125 (in FIG. 3C) is continuously etched, the exposed isolation layer 105s may be etched. The recessed region 130 may be formed in the isolation layer 105s, the buffer insulating layer 125 (in FIG. 3C) remains over the active region 105a, and thus the intermediate blocking insulating layer 125a may be formed.

While the intermediate blocking insulating layer 125a is formed by etching-back the buffer insulating layer 125 (in FIG. 3C), an exposed surface of the floating gate 118 may be cleaned. For example, the process of etching-back the buffer insulating layer 125 (in FIG. 3C) may include a process of etching a silicon oxide layer, and thus a natural oxide layer and contaminants on the exposed surface of the floating layer 118 may be removed.

Referring to FIGS. 2 and 3E, a second dielectric layer 135 may be formed on the substrate having the intermediate blocking insulating layer 125a. A high-k dielectric layer having an increased etch resistance as well as an ONO layer may be used as the second dielectric layer 135. The second dielectric layer 135 may not need to be etched during a subsequent process. The second dielectric layer 135 may include at least one of an ONO layer, an AlO layer, an HfO layer, an HfSiO layer, an HfAlO layer, a TaO layer, a ZrO layer, a LaO layer, and a TiO layer.

The first dielectric layer 110, the intermediate blocking insulating layer 125a, and the second dielectric layer 135, which are sequentially stacked on the active region 105a adjacent to both sidewalls of the floating layer 118, may constitute a blocking insulating layer 136. The first dielectric layer 110 may be composed of a tunnel oxide layer 110a interposed between the floating gate 110 and the active region 105a, and a lower blocking insulating layer 110b disposed on the active region 105a adjacent to both sidewalls of the floating layer 118. The second dielectric layer 135 may be composed of an inter-gate dielectric layer 135a interposed between a control gate to be formed by a subsequent process and the floating layer 118, and an upper blocking insulating layer 135b disposed over the active region 105 adjacent to both sidewalls of the floating gate 118. The blocking layer 136 may be composed of the lower blocking insulating layer 110b, the intermediate blocking insulating layer 125a, and the upper blocking insulating layer 135b, which are sequentially stacked.

A control gate conductive layer 140 may be formed on the substrate having the second dielectric layer 135. The control gate conductive layer 140 may be formed to include at least one of a polysilicon layer, a polycide layer, a metal layer, and a metal nitride layer. A mask pattern 145 exposing a predetermined or given region of the control gate conductive layer 140 may be formed on the control gate conductive layer 140. The mask pattern 145 may be formed of a photoresist pattern and/or a silicon nitride layer.

Referring to FIGS. 2 and 3F, the control gate conductive layer 140 (in FIG. 3E) may be etched using the mask pattern 145 as an etch mask, thereby forming a control gate 140a. When the mask pattern 145 is formed of a photoresist pattern, the mask pattern 145 may be removed. When a plurality of floating gates 118 are formed on one active region 105a, there may be as many control gates 140a formed as the number of floating gates 118. When a plurality of active regions 105a are formed, the control gates 140a may be formed to simultaneously cross the active regions 105a.

The control gate 140a may be formed to cover the top surface of the floating gate 118 and one of both sidewalls of the floating gate 118 adjacent to the active region 105a. In addition, the control gate 140a may be formed to cover the sidewalls of the floating gate 118 adjacent to the isolation layer 105s. The control gate 140a may be formed to have an extension 140e which covers the sidewalls of the floating gate 118 adjacent to the isolation layer 105s and fills the recessed region 130 of the isolation layer 105s.

When the floating gate 118 has a wider upper region 118a than a lower region 118b, the control gate 140a may be formed to have the extension 140e which covers sidewalls of the upper region 118a of the floating gate 118 adjacent to the isolation layer 105s and extends into the projecting portion of the isolation layer 105s.

Even though a plurality of floating gates 118 and a plurality of control gates 140a are formed, a process margin of the process of etching the gate conductive layer 140 using the mask pattern 145 as an etch mask may be ensured. The control gate conductive layer 140 may be etched to expose only one selected from both sidewalls of each floating gate 118 adjacent to the active region 105a. The control gates 140a may be formed by sequentially performing main etching and over etching processes with respect to the control gate conductive layer 140. The over etching process may completely electrically separate the control gates 140a from one another. For example, even though the control gates 140a are formed by the main etching process of the control gate conductive layer 140, the control gate conductive layer 140 may remain between the control gates 140a. In order to completely remove the control gate conductive layer 140 remaining between the control gates 140a, the over etching process may be performed. During the over etching process, even if a portion of the control gate 140a covering one sidewall of the floating gate 118 adjacent to the active region 105a becomes somewhat thinner, one sidewall of the floating layer 118 may still be covered. An initial thickness of the portion of the control gate 140a covering one sidewall of the floating gate 118 adjacent to the active region 105a may be sufficiently ensured.

According to example embodiments as described above, a control gate, which covers a top surface of a floating gate, one of both sidewalls of the floating gate adjacent to an active region, and both sidewalls of the floating gate adjacent to an isolation layer, is provided. An area, in which the control gate and the floating gate face each other, may be increased, and thus a coupling ratio may be increased. In addition, because the control gate covers one of both sidewalls of the floating gate adjacent to the active region, and both sidewalls of the floating gate adjacent to the isolation layer, an inter-floating gate coupling capacitance may be significantly reduced.

Increased integration of a flash memory device may be realized by increasing the height of the floating gate. Even though the height of the floating gate increases, the inter-floating gate coupling capacitance may be significantly reduced and the coupling ratio may be increased at the same time.

A blocking insulating layer may be provided, which is interposed between the portion of the control gate covering one sidewall of the floating gate, and source and drain regions. Even though the control gate covers one sidewall of the floating gate adjacent to the active region, a change in electrical potential of the active region caused by a voltage applied to the control gate may be prevented or reduced.

Also, a high-k dielectric layer having an increased etch resistance as well as an ONO layer may be used as an inter-gate dielectric layer. The inter-gate dielectric layer may not need to be etched during the fabrication process of the flash memory device. Consequently, a highly-integrated flash memory device may be provided, which has an increased coupling ratio and a significantly reduced inter-floating gate coupling capacitance and may be electrically stabilized.

Example embodiments have been disclosed herein and, although specific terms are employed, they are used and are to be interpreted in a generic and descriptive sense only, not for purpose of limitation. Accordingly, it will be understood by those of ordinary skill in the art that various changes in form and details may be made without departing from the spirit and scope of the following claims.

What is claimed is:

1. A flash memory device, comprising:
an isolation layer in a semiconductor substrate to define an active region;
a floating gate on the active region and spaced a first distance apart from the active region; and
a control gate covering a top surface of the floating gate, and one sidewall of both sidewalls of the floating gate adjacent to the active region, the portion of the control gate covering the one sidewall of the floating gate being spaced a second distance, which is greater than the first distance, apart from the active region.

2. The device according to claim 1, wherein both edges of an upper region of the floating gate overlap the isolation layer.

3. The device according to claim 2, wherein a lower region of the floating gate is self-aligned with the active region.

4. The device according to claim 1, wherein the control gate extends to the isolation layer, and covers sidewalls of the floating gate adjacent to the isolation layer.

5. The device according to claim 4, wherein the isolation layer has a projecting portion on a higher level than the active region.

6. The device according to claim 5, wherein the control gate has an extension extending into the projecting portion of the isolation layer.

7. The device according to claim 1, further comprising:
a tunnel oxide layer between the floating gate and the active region; and
an inter-gate dielectric layer between the floating gate and the control gate.

8. The device according to claim 7, wherein the inter-gate dielectric layer includes at least one of an oxide/nitride/oxide layer, an aluminum oxide layer, a hafnium oxide layer, a hafnium silicon oxide layer, a hafnium aluminum oxide layer, a tantalum oxide layer, a zirconium oxide layer, a lanthanum oxide layer, and a titanium oxide layer.

9. The device according to claim 7, further comprising:
a lower blocking insulating layer and an upper blocking insulating layer, which are sequentially stacked on the active region adjacent to both sidewalls of the floating gate, the upper blocking insulating layer being on a lower level than the control gate.

10. The device according to claim 9, wherein the lower blocking insulating layer is connected to the tunnel oxide layer, and formed of the same material as the tunnel oxide layer.

11. The device according to claim 9, wherein the upper blocking insulating layer is connected to the inter-gate dielectric layer, and formed of the same material as the inter-gate dielectric layer.

12. The device according to claim 9, further comprising:
an intermediate blocking insulating layer between the lower blocking insulating layer and the upper blocking insulating layer.

13. The device according to claim 1, further comprising:
source and drain regions in the active region adjacent to both sidewalls of the floating gate.

14. A method of fabricating a flash memory device, comprising:
forming an isolation layer defining an active region in a semiconductor substrate;
forming a first dielectric layer on the substrate having the isolation layer;
forming a floating gate partially covering the active region on the substrate having the first dielectric layer;
forming a second dielectric layer on the entire surface of the substrate having the floating gate; and
forming a control gate, which covers a top surface of the floating gate and one of both sidewalls of the floating gate adjacent to the active region, on the substrate having the second dielectric layer.

15. The method according to claim 14, wherein both edges of an upper region of the floating gate are formed to overlap the isolation layer.

16. The method according to claim 15, wherein a lower region of the floating gate is formed to be self-aligned with the active region.

17. The method according to claim 14, further comprising:
forming source and drain regions in the active region adjacent to both sidewalls of the floating gate after forming the floating gate.

18. The method according to claim 14, further comprising:
performing a gate re-oxidation process for curing the first dielectric layer adjacent to both sidewalls of the floating gate, and rounding a lower corner of the floating gate after forming the floating gate.

19. The method according to claim 14, further comprising:
forming an intermediate blocking insulating layer covering an upper portion of the active region adjacent to both sidewalls of the floating gate after forming the floating gate.

20. The method according to claim 19, wherein forming the intermediate blocking insulating layer includes:
forming an insulating layer on the substrate having the floating gate; and
etching-back the insulating layer.

21. The method according to claim 20, wherein the isolation layer is formed to have a projecting portion disposed on a higher level than the active region, the projecting portion of the isolation layer being partially etched to form a recessed region while etching back the insulating layer.

22. The method according to claim 21, wherein the control gate is formed to have an extension covering sidewalls of the upper region of the floating gate adjacent to the isolation layer and filling the recessed region.

23. The method according to claim 14, wherein the control gate is formed to cover sidewalls of the floating gate adjacent to the isolation layer.
